(19) United States
(12) Patent Application Publication
(10) Pub. No.: US 2026/0265897 A1
(43) Pub. Date: Sep. 10, 2026

(54) MASK PLATE AND METHOD FOR MANUFACTURING SAME, MASK DEVICE, AND EVAPORATION-DEPOSITION METHOD

(71) Applicants: Yunnan Invensight Optoelectronics Technology Co., Ltd., Yunnan (CN); BOE Technology Group Co., Ltd., Beijing (CN); Beijing BOE Technology Development Co., Ltd., Beijing (CN)

(72) Inventors: Chao PU, Beijing (CN); Dacheng ZHANG, Beijing (CN); Qingshan SHAN, Beijing (CN); Xiaochuan CHEN, Beijing (CN); Yinhu HUANG, Beijing (CN); Shengji YANG, Beijing (CN); Pengcheng LU, Beijing (CN); Zhao MA, Beijing (CN); Yingbing ZHANG, Beijing (CN); Liuzeming QU, Beijing (CN); Qi SU, Beijing (CN); Zhuoyang XIE, Beijing (CN)

(73) Assignees: Yunnan Invensight Optoelectronics Technology Co., Ltd., Yunnan (CN); BOE Technology Group Co., Ltd., Beijing (CN); Beijing BOE Technology Development Co., Ltd., Beijing (CN)

(21) Appl. No.: 18/847,752

(22) PCT Filed: Nov. 1, 2023
(86) PCT No.: PCT/CN2023/129025

§ 371 Date: Sep. 17, 2024

(51) Int. Cl. C23C 14/04

(52) U.S. Cl. CPC C23C 14/042

(57) ABSTRACT

Provided is a mask plate. The mask plate includes a plate body, wherein the plate body has a first surface and a second surface opposite to the first surface, and the first surface being in contact with a to-be-evaporation-deposited object; wherein a plurality of evaporation-deposition holes and a plurality of grooves are defined in the plate body, wherein the evaporation-deposition holes extend through the first surface and the second surface, and the plurality of grooves are disposed in the second surface between the plurality of evaporation-deposition holes.

### CROSS-REFERENCE TO RELATED APPLICATION

This application is a U.S. national phase application based on PCT/CN2023/129025, filed on Nov. 1, 2023, the content of which is incorporated herein by reference in its entirety.

### TECHNICAL FIELD

The present disclosure related the field of display technologies, and in particular, relates to a mask plate and a method for manufacturing the same, a mask device, and an evaporation-deposition method.

### BACKGROUND

The evaporation-deposition process is one of the important processes for manufacturing display panels, and the evaporation-deposition process requires to form a plurality of display film layers on a to-be-evaporation-deposited object by using a mask plate.

### SUMMARY

Embodiments of the present disclosure provide a mask plate and a method for manufacturing the same, a mask device, and an evaporation-deposition method. The technical solutions are as follows.

According to some embodiments of the present disclosure, a mask plate is provided. The mask plate includes a plate body, the plate body has a first surface and a second surface opposite to the first surface, and the first surface being in contact with a to-be-evaporation-deposited object; wherein a plurality of evaporation-deposition holes and a plurality of grooves are defined in the plate body, wherein the evaporation-deposition holes extend through the first surface and the second surface, and the plurality of grooves are disposed in the second surface between the plurality of evaporation-deposition holes.

In some embodiments, a cross-section of each of the plurality of grooves becomes progressively smaller in a direction from the second surface towards the first surface, and is perpendicular to a thickness direction of the plate body.

In some embodiments, a width of an opening of each of the plurality of grooves is L1, and a distance between the openings of adjacent two of the plurality of grooves is L2, wherein L1 and L2 satisfy a relationship: L1≤L2≤2*L1.

In some embodiments, each of the plurality of evaporation-deposition hole includes a first hole section and a second hole section; wherein a first end of the first hole section is close to the second surface, a second end of the first hole section is on the first surface, an orthographic projection of the first end on the first surface is within an orthographic projection of the second end on the first surface; and a third end of the second hole section is close to the first surface, a fourth end of the second hole section is on the second surface, an orthographic projection of the third end on the first surface is within an orthographic projection of the fourth end on the first surface.

In some embodiments, an inner wall of the first hole section is a first concave surface recessed in a direction towards the second surface.

In some embodiments, an orthographic projection of a first point of the first end on the first surface is on a line connecting a second point of the second end to a center point of the second end, and a first angle is formed between a line connecting the first point to the second point and the first surface; an orthographic projection of a third point of the third end on the second surface is on a line connecting a fourth point of the fourth end to a center point of the fourth end, and a second angle is formed between a line between the third point and the fourth point and the second surface; wherein the first angle is less than or equal to the second angle.

In some embodiments, an inner wall of the second hole section is a second concave surface recessed in a direction towards the first surface; and a radius of curvature of the first concave surface is smaller than a radius of curvature of the second concave surface.

In some embodiments, a surface roughness of the inner wall of the second hole section is less than a surface roughness of the inner wall of the first hole section.

In some embodiments, the evaporation-deposition hole includes a first hole section, wherein a first end of the first hole section is close to the second surface and a second end of the first hole section is on the first surface, an orthographic projection of the first end on the first surface is within an orthographic projection of the second end on the first surface.

In some embodiments, a dimension of the groove in a thickness direction of the plate body is smaller than a dimension of the first hole section in the thickness direction of the plate body, and the dimension of the groove in the thickness direction of the plate body is smaller than the dimension of the second hole section in the thickness direction of the plate body.

In some embodiments, a dimension of the groove in a thickness direction of the plate body ranges from 1 μm to 30 μm.

In some embodiments, a distance between the orthographic projection of the first end on the first surface and the orthographic projection of the second end on the first surface is L3, and a distance between the orthographic projection of the third end on the second surface and the orthographic projection of the fourth end on the second surface is L4, wherein L1<L4 and L1<L3.

In some embodiments, the evaporation-deposition hole further includes a third hole section, and the third hole section is connected to the first hole section and the second hole section, and is between the first hole section and the second hole section; wherein an orthographic projection of the third hole section on the first surface is within an orthographic projection of the first hole section on the first surface, and the orthographic projection of the third hole section on the first surface is within an orthographic projection of the second hole section on the first surface.

In some embodiments, a dimension of the third hole section in the thickness direction of the plate body is smaller than a dimension of the first hole section in the thickness direction of the plate body.

In some embodiments, side walls of the third hole section are smooth.

In some embodiments, a tip structure protruding away from the first surface is disposed at a bottom of each of the plurality of grooves; or a tip structure protruding away from the first surface is disposed at the second surface, and the tip structure is between adjacent two of the plurality of grooves.

In some embodiments, a material of the plate body is invar or silicon.

In some embodiments, the to-be-evaporation-deposited object is a silicon-based driving backplane.

In some embodiments, the silicon-based driving backplane includes a plurality of display regions, and each of the plurality of display regions includes a plurality of sub-pixel regions distributed in an array; wherein the plurality of evaporation-deposition holes are in one-to-one correspondence with the plurality of sub-pixel regions; or the plurality of evaporation-deposition holes are in one-to-one correspondence with the plurality of display regions.

According to some embodiments of the present disclosure, a method for manufacturing a mask plate is provided. The method includes providing a plate body, wherein the plate body has a first surface and a second surface opposite to the first surface, and the first surface being in contact with a to-be-evaporation-deposited object; and processing a plurality of evaporation-deposition holes and a plurality of grooves in the plate body, wherein the evaporation-deposition holes extend through the first surface and the second surface, and the plurality of grooves are disposed on the second surface between the plurality of evaporation-deposition holes.

According to some embodiments of the present disclosure, a mask device is provided. The mask device includes a support element and the mask plate as described above, wherein the support element is disposed on a side, away from the first surface, of the plate body and arranged along an edge of the plate body.

In some embodiments, the mask plate includes a first mask plate and a second mask plate, an orthographic projection of the evaporation-deposition holes of the first mask plate on the to-be-evaporation-deposited object is within an orthographic projection of the evaporation-deposition holes of the second mask plate on the to-be-evaporation-deposited object; wherein the first mask plate and the second mask plate are configured to manufacture different film layers.

In some embodiments, the mask plate further includes an electrostatic generator, wherein the electrostatic generator is configured to supply a voltage ranging from 500V to 1500V to the mask plate.

### BRIEF DESCRIPTION OF DRAWINGS

In order to more clearly illustrate the technical solutions in the embodiments of the present disclosure, the accompanying drawings that need to be used in the description of the embodiments are briefly introduced below. It is obvious that the accompanying drawings in the following description are only some of the embodiments of the present disclosure, and a person of ordinary skill in the art can acquire other accompanying drawings based on these drawings without creative labor.

FIG. 1 is a schematic diagram of a cross-sectional structure of a mask plate according to some embodiments of the present disclosure;

FIG. 2 is a schematic diagram of a planar structure of a mask plate according to some embodiments of the present disclosure;

FIGS. 3 to 7 are schematic diagrams of a cross-sectional structure of another mask plate according to some embodiments of the present disclosure;

FIG. 8 is a schematic diagram of a planar structure of another mask plate according to some embodiments of the present disclosure;

FIG. 9 is a schematic diagram of a planar structure of another mask plate according to some embodiments of the present disclosure;

FIG. 10 is a schematic diagram of a planar structure of a first hole section and a second hole section according to some embodiments of the present disclosure;

FIG. 11 is a schematic diagram of a cross-sectional structure when evaporation depositing a to-be-evaporation-deposited object according to some embodiments of the present disclosure;

FIG. 12 is a schematic diagram of a cross-sectional structure of another mask plate according to some embodiments of the present disclosure;

FIG. 13 is a schematic diagram of a planar structure of a silicon-based driving backplane according to some embodiments of the present disclosure;

FIG. 14 is a schematic diagram of a cross-sectional structure of a display panel according to some embodiments of the present disclosure;

FIG. 15 is a schematic diagram of a planar structure of a mask plate according to some embodiments of the present disclosure;

FIG. 16 is a schematic diagram of a planar structure of a light-emitting layer of another display panel according to some embodiments of the present disclosure;

FIG. 17 is a schematic flow diagram of a method for manufacturing a mask plate according to some embodiments of the present disclosure;

FIG. 18 is a schematic diagram of a cross-sectional structure of a mask device according to some embodiments of the present disclosure;

FIG. 19 is a schematic diagram of a planar structure of a mask device according to some embodiments of the present disclosure; and

FIG. 20 is a flow chart of an evaporation-deposition method according to some embodiments of the present disclosure.

### DETAILED DESCRIPTION

In order to make the objects, technical solutions and advantages of the present disclosure clearer, the embodiments of the present disclosure are described in further detail below in conjunction with the accompanying drawings.

The terms used in the embodiments portion of the present disclosure are used only for the purpose of explaining the embodiments of the present disclosure and are not intended to limit the present disclosure. Unless otherwise defined, technical terms or scientific terms used in the embodiments of the present disclosure shall have the ordinary meaning understood by a person of ordinary skill in the art to which the present disclosure belongs. The terms “first,” “second,” “third,” and the like used in the description of the patent application and the claims of the present disclosure do not indicate any order, number, or importance, but are merely used to distinguish different components. Similarly, the words “a” or “one” and similar terms do not indicate a limitation of quantity, but rather the existence of at least one. Similar terms such as “includes” or “contains” mean that the components or objects appearing prior to “includes” or “contains” encompasses the components or objects that appearing upon “includes” or “contains”, and do not exclude other components or objects. Orientation terms mentioned in the present disclosure, such as “top”, “bottom”, “up”, “down”, “left”, “right”, or the like, are only references to the orientation of the accompanying drawings. Therefore, the orientation terms used are intended to better and more clearly illustrate and understand the present disclosure embodiments, and do not indicate or imply that the device or component referred to must have a particular orientation, or be constructed and operated in a particular orientation, which are not to be construed as a limitation of the embodiments of the present disclosure.

In related technologies, the mask plate includes a plate body, and the plate body has a contact surface and an evaporation-deposition surface that are opposite to each other. A plurality of evaporation-deposition holes are defined in the plate body, and the evaporation-deposition hole extends through the contact surface and the evaporation-deposition surface. The evaporation-deposition surface of the plate body is planar.

However, an evaporation-deposition material is attached to the evaporation-deposition surface in the direction pointing from the evaporation-deposition surface towards the contact surface to form a film, and an adsorption capacity of the plate body with a planar evaporation-deposition surface for the evaporation-deposition material is weak. During a process of manufacturing the display panel by using the mask plate (e.g., moving, replacing the mask plate), the evaporation-deposition material attached to the evaporation-deposition surface is prone to falling off, which contaminates the target material and the evaporation-deposition chamber, and thus affects the yield of the product.

FIG. 1 is a schematic diagram of a cross-sectional structure of a mask plate according to some embodiments of the present disclosure. As shown in FIG. 1, the mask plate 1 includes a plate body, the plate body 100 has a first surface 101 and a second surface 102 opposing to the first surface 101. The first surface 101 is configured to contact a to-be-evaporation-deposited object, and the first surface 101 is also referred to as a contact surface. The evaporation-deposition material is evaporation deposited, attached, and formed into a film in the direction from the second surface 102 to the first surface 101, and the second surface 102 is also referred to as an evaporation-deposition surface.

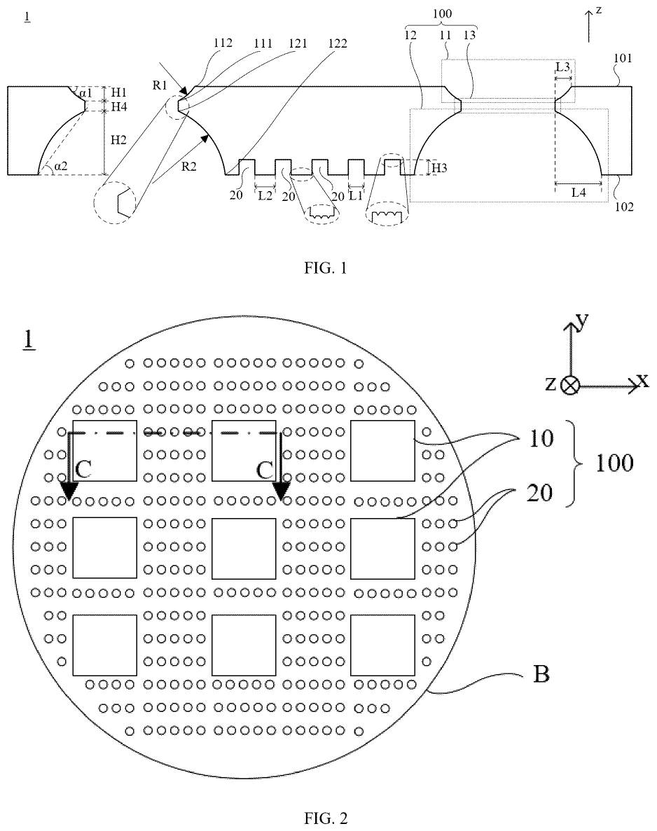

FIG. 2 is a schematic diagram of the planar structure of a mask plate according to some embodiments of the present disclosure, and FIG. 1 is a schematic diagram of the cross-sectional structure along the cross-section line CC in FIG. 2, that is, FIG. 2 is a bottom view of FIG. 1. In conjunction with FIGS. 1 and 2, a plurality of evaporation-deposition holes 10 and a plurality of grooves 20 are defined in the plate 100. The evaporation-deposition holes 10 extend through the first surface 101 and the second surface 102, and the grooves 20 are disposed on the second surface.

Because the adhesion of the evaporation-deposition material is directly proportional to the friction coefficient between the evaporation-deposition material and the mask plate and the contact area, in the case that the friction coefficient between the evaporation-deposition material and the mask plate remains unchanged, the plurality of grooves 20 disposed on the second surface 102 cause the contact area between the evaporation-deposition material and the mask plate to be larger on the second surface 102, such that the adhesion of the evaporation-deposition material is larger, which is conducive to the adsorption of the evaporation-deposition material on the mask plate, and the contamination caused by the shedding of the evaporation-deposition material is reduced and the product yield is improved.

In normal evaporation-deposition process, the evaporation-deposition material is in the form of small and uniform particles. The evaporation-deposition material that passes through the evaporation-deposition holes adheres to the to-be-evaporation-deposited object to form a film structure having uniform thickness, and the evaporation-deposition material that does not pass through the evaporation-deposition holes adheres to the surface of the mask plate. Here, the contamination caused by the evaporation-deposition material falling off specifically refers to the contamination to the evaporation-deposition source or the to-be-evaporation-deposited object caused by the evaporation-deposition material attached to the surface of the mask plate falling off during the evaporation-deposition process or the process of replacing the to-be-evaporation-deposited object.

For example, the evaporation-deposition material attached to the surface of the mask plate falls off and forms a large slice structure. The slice structure falls onto the evaporation-deposition source (e.g., the target) and contaminate the evaporation-deposition source. For example, since evaporation-deposition is usually performed by heating the evaporation-deposition source, an upward hot air flow exists, and the portion of the evaporation-deposition material is blown to the to-be-evaporation-deposited object by the hot air flow upon falling off. The larger slice structure forms a bump on the film layer structure that should be formed with uniform thickness, which affects the effect of evaporation-deposition, and is bad for the yield of the product.

In the case that the to-be-evaporation-deposited object is a substrate of a display panel, the bump leads to an abnormality of displaying bright spots or displaying dark spots, affecting the display effect.

Exemplarily, as shown in FIG. 2, the plurality of evaporation-deposition holes 10 are distributed in an array on the mask plate 1.

In some embodiments, the shape of the orthographic projection of the evaporation-deposition holes 10 on the second surface 102 is a rectangle as shown in FIG. 2, or other polygonal shape such as a pentagon, a circle, an oval, or the like.

In some embodiments, the mask plate 1 further includes a plurality of evaporation-deposition holes 10 with different shapes.

In some embodiments, the plurality of grooves 20 are distributed between any two adjacent evaporation-deposition holes 10.

In some embodiments, the plurality of grooves 20 are distributed only between two adjacent evaporation-deposition holes 10 in the first direction x, or only between two adjacent evaporation-deposition holes 10 in the second direction y. The first direction x is intersected with the second direction y, and both the first direction x and the second direction y are perpendicular to the thickness direction z of the plate body 100.

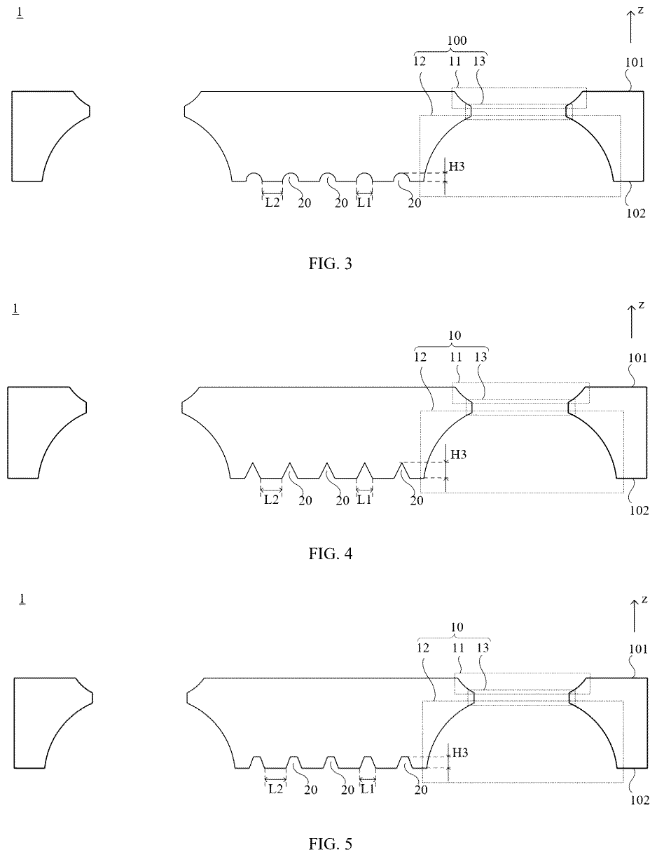

Exemplarily, as shown in FIG. 1, the area of the cross-section of the groove 20 is constant in the direction from the second surface 102 to the first surface 101. The cross-section of the groove 20 is perpendicular to the thickness direction of the plate body 100. FIGS. 3 to 7 are schematic diagrams of cross-sectional structures of another mask plate according to some embodiments of the present disclosure. As shown in FIGS. 3 to 6, the area of the cross-section of the groove 20 becomes progressively smaller in the direction from the second surface 102 to the first surface 101. As shown in FIG. 7, in the direction from the second surface 102 to the first surface 101, the area of the cross-section of the groove 20 first remains constant, then decreases, and then remains constant. That is, in the embodiments shown in FIGS. 3 to 7, the area of the opening of the groove 20 is greater than the area of the bottom of the groove 20. This design for the cross-sectional area of the groove 20 facilitates the attachment of the evaporation-deposition material.

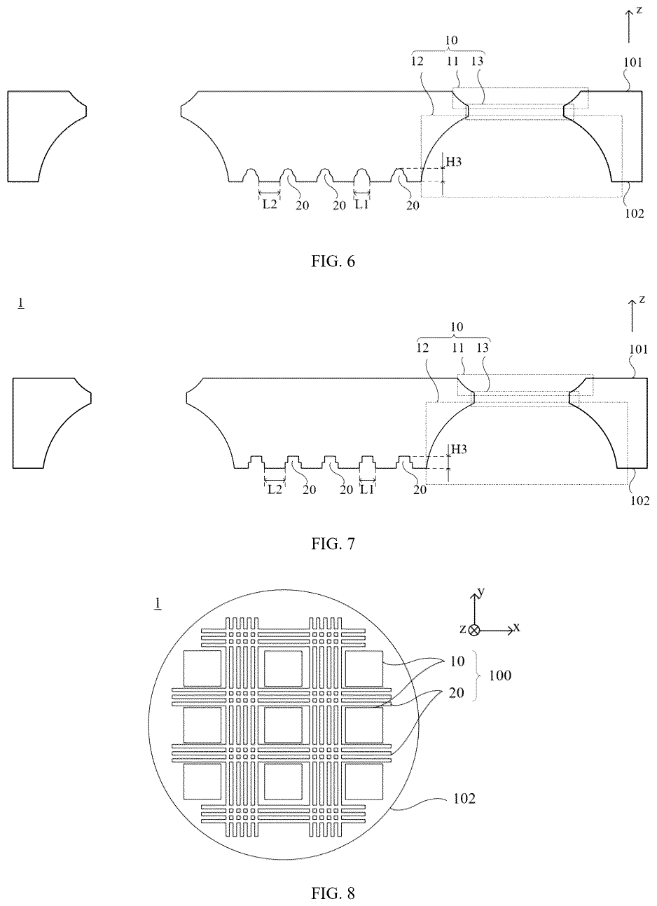

In some embodiments, the shape of the groove is a pit. Specifically, the shape of the groove is cylindrical, and the corresponding cross-sectional diagram is shown in FIG. 1 and the corresponding bottom view is shown in FIG. 2. Alternatively, the shape of the groove is prismatic, and the corresponding cross-sectional diagram is shown in FIG. 1. Alternatively, the shape of the groove is hemispherical, and the corresponding cross-sectional diagram is shown in FIG. 3. Alternatively, the shape of the groove is conical, and the corresponding cross-sectional diagram is shown in FIG. 4. Alternatively, the shape of the groove is rounded or prismatic, and the corresponding cross-sectional diagram is shown in FIG. 5. Alternatively, the shape of the groove is two stacked hemispheres of different dimensions, and the corresponding cross-sectional diagram is shown in FIG. 6. Alternatively, the shape of the groove is two stacked pillars of different dimensions, and the corresponding cross-sectional diagram is shown in FIG. 7.

FIG. 8 is a schematic diagram of the planar structure of another mask plate according to some embodiments of the present disclosure. As shown in FIG. 8, the shape of the grooves 20 is a strip, the length directions of the plurality of grooves 20 are different, and the plurality of grooves 20 are intersected with each other to form a mesh structure. Optionally, as shown in FIG. 8, in the plurality of strip grooves 20, the length direction of a first portion of the grooves 20 is a first direction x, and the length direction of a second portion of the grooves 20 is a second direction y. The first portion of grooves 20 is intersected with the second portion of grooves 20. By providing the strip grooves 20, the contact area between the evaporation-deposition material and the second surface 102 is increased, and the evaporation-deposition material is better adhered to the second surface 102, which reduces the possibility of contamination caused by the evaporation-deposition material falling off during the evaporation-deposition process, and improves the product yield.

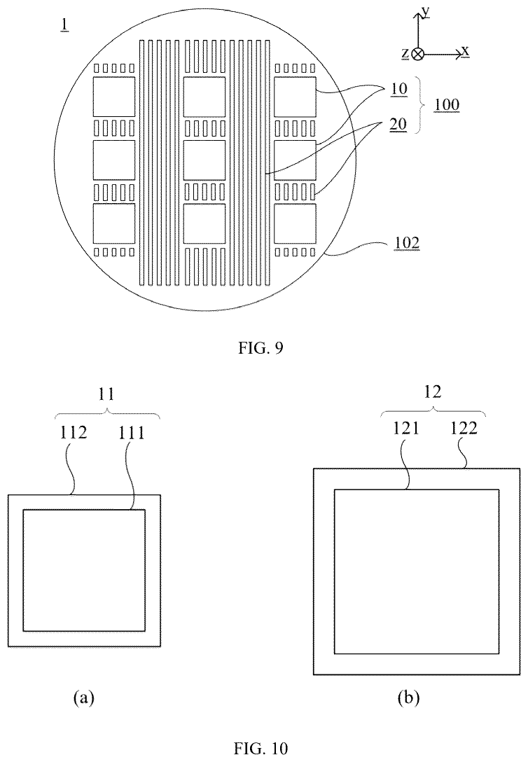

FIG. 9 is a schematic diagram of a planar structure of another mask plate according to some embodiments of the present disclosure. As shown in FIG. 9, the shape of the groove 20 is a strip, and the plurality of grooves 20 have the same length direction. Optionally, as shown in FIG. 9, the length directions of the plurality of strip grooves 20 are all the second direction y.

In some embodiments, in the embodiments shown in FIGS. 8 and 9, the cross-sectional figure of the strip grooves 20 is: a rectangle as shown in FIG. 1, a semi-circle as shown in FIG. 3, a triangle as shown in FIG. 4, a trapezoid as shown in FIG. 5, two stacked semi-circles of different dimensions as shown in FIG. 6, or two stacked rectangles of different dimensions as shown in FIG. 7.

Exemplarily, referring again to FIG. 1, the width of the opening of the groove 20 is L1, the distance between the openings of two adjacent grooves 20 is L2, and L1 and L2 satisfy the relationship: L1≤L2≤2*L1. In the case that L1 is too large or L2 is too large, the quantity of grooves 20 that can be made in a region with the same area decreases, and the sidewalls of the grooves 20 are reduced. Hence, the increased contact area on the second surface 102 is reduced, which is not conducive to enhancing the adsorption of the evaporation-deposition material on the second surface B. In addition, in the case that L2 is too small, the grooves scratch the operator. Optionally, the groove 20 is processed on the mask plate 1 by etching silicon, which facilitates the preparation of the groove 20 in which L1 and L2 satisfy the above relational equation due to the high precision of the process of etching silicon.

FIG. 10 is a schematic diagram of a planar structure of a first hole section and a second hole section according to some embodiments of the present disclosure. Exemplarily, the evaporation-deposition hole 10 includes a first hole section 11 and a second hole section 12. In conjunction with FIG. 1 and part (a) of FIG. 10, a first end 111 of the first hole section 11 is close to the second surface 102, and a second end 112 of the first hole section 11 is on the first surface 101. An orthographic projection of the first end 111 on the first surface 101 is within an orthographic projection of the second end 112 on the first surface 101. In conjunction with FIG. 1 and part (b) of FIG. 10, a third end 121 of the second hole section 12 is close to the first surface 101, and a fourth end 122 the second hole section 12 is on the second surface 102. An orthographic projection of the third end 121 on the first surface 101 is within an orthographic projection of the fourth end 122 on the first surface 101. That is, the first hole section 11 is close to the first surface 101 and the second hole section 12 is close to the second surface 102. An area of the orthographic projection of a side, away from the second surface 102, of the first hole section 11 on the first surface is greater than an area of the orthographic projection of a side, close to the second surface 102, of the first hole section 11 on the first surface 101. An area of the orthographic projection of a side, away from the first surface 101, of the second hole section 12 on the first surface 101 is greater than an area of the orthographic projection of a side, close to the first surface 101, of the second hole section 12 on the first surface 101.

Exemplarily, as shown in FIG. 1, the evaporation-deposition hole 10 further includes a third hole section 13. The third hole section 13 is connected to the first hole section 11 and the second hole section 12, and the third hole section 13 is disposed between the first hole section 11 and the second hole section 12. An orthographic projection of the third hole section 13 on the first surface 101 is within an orthographic projection of the first hole section 11 on the first surface 101, and an orthographic projection of the third hole section 13 on the first surface 101 is within an orthographic projection of the second hole section 12 on the first surface 101. Since the radial dimension of the third hole section 13 is smaller than the radial dimension of the first hole section 11 and smaller than the radial dimension of the second hole section 12, the radial dimension of the third hole section 13 determines the evaporation-deposition dimension of the evaporation-deposition hole 10.

In some embodiments, as shown in FIG. 1, an orthographic projection of the end, close to the first surface 101, of the third hole section 13 on the first surface 101 coincides with an orthographic projection of the end, away from the first surface 101, of the third hole section 13 on the first surface 101.

In some embodiments, the orthographic projection of the end, close to the first surface 101, of the third hole section 13 on the first surface 101 is within the orthographic projection of the end, away from the first surface 101, of the third hole section 13 on the first surface 101. In this way, the end, close to the first surface 101, of the third hole section 13 determines the dimension of the evaporation-deposition holes 10. Alternatively, the orthographic projection of the end, close to the first surface 101, of the third hole section 13 on the first surface 101 is outside the orthographic projection of the end, away from the first surface 101, of the third hole section 13 on the first surface 101. In this way, the end, away from the first surface 101, of the third hole section 13 determines the evaporation-deposition dimension of the evaporation-deposition holes 10.

In some embodiments, the orthographic projection of the middle portion of the third hole section 13 on the first surface 101 is within the orthographic projection of the end, away from the first surface 101, of the third hole section 13 on the first surface 101, and the orthographic projection of the middle portion of the third hole section 13 on the first surface 101 is within the orthographic projection of the end, away from the first surface 101, of the third hole section 13 on the first surface 101. In this way, the radial dimension at the narrowest middle portion of the third hole section 13 determines the evaporation-deposition dimension of the evaporation-deposition hole 10.

Exemplarily, the sidewalls of the third hole section 13 are smooth. Smooth sidewalls herein refer that the surface does not have protruding ribs or sharp corners. Since in the actual evaporation-deposition process, a voltage is usually supplied to the mask plate 1 to increase the adsorption force of the mask plate 1 to the evaporation-deposition material by electrostatic adsorption, the smooth sidewall of the third hole section 13 can reduce the occurrence of a tip discharge at the third hole section 13 resulting in poor evaporation-deposition during the process. Optionally, the sides of the third hole section 13 is curved or flat as shown in FIG. 1.

In some embodiments, the side wall of the third hole section 13 is smoothly connected to the side wall of the first hole section 11, and the side wall of the third hole section 13 is smoothly connected to the side wall of the second hole section 12. This design reduces the occurrence of tip discharge at the connection between the third hole section 13 and the first hole section 11 and at the connection between the third hole section 13 and the second hole section 12 which results in poor evaporation-deposition during the actual evaporation-deposition process.

Exemplarily, as shown in FIG. 1, a tip structure protruding away from the first surface 101 is disposed at the bottom of the groove 20, and a tip structure protruding away from the first surface 101 is disposed on the second surface 102, and the tip structure is disposed between two adjacent grooves 20. In the actual evaporation-deposition process, a voltage is usually supplied to the mask plate 1 to increase the adsorption force of the mask plate 1 to the evaporation-deposition material by electrostatic adsorption, and the tip structure increases the adsorption force of the second surface 102 to the evaporation-deposition material. Optionally, the tip structure is a raised plurality of sharp corners or a raised plurality of edges.

In other possible embodiments, the tip structures are disposed only at the bottom of the grooves 20, or the tip structures are disposed only on the second surface 102 between two adjacent grooves 20.

FIG. 11 is a schematic diagram of a cross-sectional structure according to some embodiments of the present disclosure when evaporation depositing a to-be-evaporation-deposited object. As shown in FIG. 11, the to-be-evaporation-deposited object 4 is disposed on one side of the first surface 101 of the mask plate 1, and the evaporation-deposition source is disposed on one side of the second surface 102 of the mask plate 1. In conjunction with FIGS. 1 and 10, the dimension of the evaporation-deposition depends on the dimension of the third hole section 13. However, in the actual evaporation-deposition process, in the case that the mask plate 1 and the to-be-evaporation-deposited object 4 are accurately aligned, i.e., the third hole section 13 of the evaporation-deposition hole 10 is accurately aligned with the target position of the evaporation-deposition on the to-be-evaporation-deposited object 4, due to the thickness of the mask plate 1, the extended line of a line connecting the evaporation-deposition source 3 to an end, away from the first surface 101, of a portion of the third hole section 13 falls into a target evaporation-deposition position of the to-be-evaporation-deposited object 4. Therefore, a D region is disposed on the to-be-evaporation-deposited object 4 as shown in FIG. 10. The evaporation-deposition material is not adhered to the to-be-evaporation-deposited object in the D region or only a small amount of evaporation-deposition material is adhered to the to-be-evaporation-deposited object in the D region. Since the region D is within the evaporation-deposition region, the region D is also referred to as the inner shadow region D.

In the mask plate 1 including the first hole section 11 but not including the second hole section 12, the evaporation-deposition accuracy depends on the dimension of the side, away from the first surface 101, of the first hole section 11, and the distance between the place that determines the evaporation-deposition accuracy and the to-be-evaporation-deposited object is longer. Compared to this mask plate, in the case that the overall thickness of the mask plate 1 remains unchanged, the mask plate 1 in the embodiments shown in FIG. 1 has both the first hole section 11 and the second hole section 12, and the distance between the place that determines the evaporation-deposition accuracy and the to-be-evaporation-deposited object is shorter, and thus the area of the inner shadow region D is smaller, which is conducive to improving the evaporation-deposition accuracy on the to-be-evaporation-deposited object.

Exemplarily, as shown in FIG. 1, the inner wall of the first hole section 11 is a first concave surface recessed in a direction towards the second surface 102. This design allows the contact edge of the first surface 101 with the to-be-evaporation-deposited object to be as far away as possible from the target position of evaporation-deposition, such that the impurity particles adhered due to contact with the to-be-evaporation-deposited object are away from the target position of evaporation-deposition and the product yield is improved. The to-be-evaporation-deposited object is a substrate, the impurity particles are materials of the light-emitting layer in the display panel, or materials falling off the mask plate, or the like. The target position of the evaporation-deposition is a display region or a sub-pixel region in the display panel.

Exemplarily, as shown in FIG. 1, the inner wall of the second hole section 12 is a second concave surface recessed in a direction towards the first surface 101. This design allows the evaporation-deposition process to be carried out in a way as unlikely as possible that the inner wall of the second hole section 12 is between lines connecting the evaporation-deposition source to the to-be-evaporation-deposited regions of the to-be-evaporation-deposited object, i.e., the inner wall of the second hole section 12 does not block the evaporation-deposition material from attaching to the to-be-evaporation-deposited object as much as possible.

Exemplarily, in conjunction with FIGS. 1 and 11, the radius R1 of curvature of the first concave surface is smaller than the radius R2 of curvature of the second concave surface. The design allows the distance between the side, away from the first surface 101, of the first hole section 11 and the second surface 102 to be shorter, i.e., allows the distance between the place that determines the evaporation-deposition accuracy in the mask plate 1 and the to-be-evaporation-deposited object 4 to be shorter, such that the area of the inner shaded region D is smaller, which is conducive to increasing the amount of evaporation-deposition material attached to the to-be-evaporation-deposited object 4.

In some embodiments, as shown in FIG. 1, the dimension H4 of the third hole section 13 in the thickness direction z of the plate body 100 is smaller than the dimension H1 of the first hole section 11 in the thickness direction of the plate body 100, such that the distance between the place that determines the evaporation-deposition accuracy in the third hole section 13 and the to-be-evaporation-deposited object 4 is as short as possible, and the area of the inner shaded region D is smaller, which is conducive to improving the plating accuracy on the to-be-evaporation-deposited object 4.

Exemplarily, as shown in FIG. 1, an orthographic projection of a first point of the first end 111 on the first surface 101 is on a line connecting a second point of the second end 112 to a center point of the second end 112, and a first angle α1 is formed between a line connecting the first point to the second point and the first surface 101. An orthographic projection of a third point of the third end 121 on the second surface 102 is on a line connecting a fourth point of the fourth end 122 to a center point of the fourth end 122. A second angle α2 is formed between the line connecting the third point to the fourth point and the second surface 102. The first angle al is less than or equal to the second angle α2. The design defines the relationship between the first angle α1 and the second angle α2 based on the first concave surface of the first hole section 11, and allows the first hole section 11 to have a greater radial space, such that the attached impurity particles are as far away as possible from the target position of evaporation-deposition.

Exemplarily, as shown in FIG. 1, the distance between the orthographic projection of the first end on the first surface 101 and the orthographic projection of the second end on the first surface 101 is L3, the distance between the orthographic projection of the third end on the second surface 102 and the orthographic projection of the fourth end on the second surface 102 is L4, and L1<L4, L1<L3. The design allows to process grooves 20 as many as possible, such that the amount of contact area between the evaporation-deposition material and the second surface 102 is increased, and the adsorption capacity of the mask plate to the evaporation-deposition material is enhanced.

Exemplarily, the surface roughness of the inner wall of the second hole section 12 is less than the surface roughness of the inner wall of the first hole section 11. The surface roughness of the inner wall of the second hole section 12 is less, and thus the surface of the inner wall of the second hole section 12 is smoother, which facilitates removing the dried evaporation-deposition material disposed therein upon use of the mask plate 1, and facilitates repeated use of the mask plate 1.

Exemplarily, as shown in FIG. 1, the dimension H3 of the groove 20 in the thickness direction z of the plate body 100 is smaller than the dimension H1 of the first hole section 11 in the thickness direction z of the plate body 100, and the dimension H3 of the groove 20 in the thickness direction z of the plate body 100 is smaller than the dimension H2 of the second hole section 12 in the thickness direction z of the plate body 100. The groove 20 cannot be too deep, otherwise it is hard to be cleaned, which is not conducive to repeated use of the mask plate 1. Moreover, in the case that the groove 20 is too deep, the more evaporation-deposition material can be accommodated. As the evaporation-deposition material accumulates in the groove during the evaporation-deposition process, the mass of the mask plate increases, and a defective deformation of the mask plate occurs during the evaporation-deposition process. That is, a gap appears between the first surface 101 of the mask plate and the to-be-evaporation-deposited object, and the evaporation-deposition material enters into the gap, which affects the quality of evaporation-deposition and reduces the yield of the product.

Exemplarily, the dimension H3 of the groove 20 in the thickness direction z of the plate body 100 ranges from 1 μm to 30 μm, for example, 15 μm. The groove 20 in this dimension range can both increase the contact area between the evaporation-deposition material and the mask plate 1 on the second surface 102, such that the plurality of grooves 20 are able to accommodate a larger amount of evaporation-deposition material. For example, the film layer of evaporation-deposition material during an evaporation-deposition equipment preventive maintenance cycle is accommodated, such that the mask plate can be cleaned upon evaporation depositing a plurality of to-be-evaporation-deposited objects 4, instead of needing to clean the evaporation-deposition material in the plurality of grooves 20 upon evaporation depositing a few to-be-evaporation-deposited objects 4, and the above disadvantages of the mask plate not being easy to be cleaned and the deformation of the mask plate are not appear due to the excessive depth of the grooves 20.

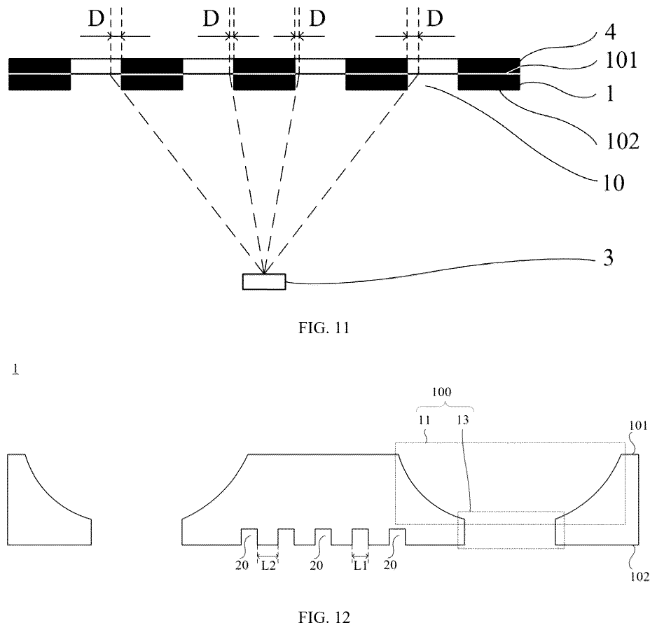

FIG. 12 is a schematic diagram of a cross-sectional structure of another mask plate according to some embodiments of the present disclosure. Compared to the embodiments shown in FIG. 1, in the mask plate 1 shown in FIG. 12, the evaporation-deposition holes include a first hole section 11 and do not include a second hole section 12. In the embodiments shown in FIG. 12, the first hole section 11 is close to the first surface 101, and an area of an orthographic projection of the side, away from the second surface 102, of the first hole section 11 on the second surface 102 is larger than an area of an orthographic projection of the side, close to the second surface 102, of the first hole section 11 on the second surface 102.

In some embodiments, as shown in FIG. 12, the mask plate 1 further includes a third hole section 13, the third hole section 13 is disposed on the side, away from the first surface 101, of the first hole section 11. Since the radial dimension of the third hole section 13 is smaller than the radial dimension of the first hole section 11, the radial dimension of the third hole section 13 determines the evaporation-deposition dimension of the evaporation-deposition hole 10.

According to the above contents, in the mask plate described in FIG. 1, because the surface roughness of the second hole section 12 is low, upon processing the first hole section 11, the second hole section 12, and the third hole section 13, it is usually also necessary to perform surface etching treatment by a chemical reagent on the inner wall of the second hole section 12, such that the inner wall of the second hole section 12 is smooth. However, in this step, the chemical reagent also corrodes the already processed first hole section 11, thereby affecting the lateral dimension where the first hole section 11 is connected to the second hole section 12 (i.e., the third hole section 13), which causes a certain difference between the dimension of the evaporation-deposition hole in the theoretical design and the dimension of the actual processed hole, and affects the precision of the evaporation-deposition holes. In the embodiments shown in FIG. 12, on the other hand, since the second hole section 12 is not present, it is not needed to perform surface corrosion treatment by chemical reagent upon processing the first hole section 11 and the third hole section 13, and thus the difference between the dimension of the evaporation-deposition hole in the theoretical design and the dimension of the actual processed hole in the embodiments shown in FIG. 11 is smaller.

In the embodiments shown in FIG. 12, the dimension limitations and the like of the first hole section 11 and the groove 20 are referred to the above contents, which are not repeated herein.

Exemplarily, the material of the plate body 100 is invar or silicon. The strength and hardness of these two materials allow the center and periphery of the mask plate to fit more closely with the to-be-evaporation-deposited object, and the problems such as large concave deformation during using do not affect the evaporation-deposition quality.

Exemplarily, the to-be-evaporation-deposited object is a driving backplane. Optionally, the driving backplane includes an active layer, a gate insulating layer, a gate layer, an interlayer insulating layer, a source-drain layer, and a flat layer which are stacked, wherein a plurality of active regions in the active layer, a plurality of gates in the gate layer, and a plurality of sources and drains in the source-drain layer constitute a plurality of thin film transistors.

Exemplarily, the to-be-evaporation-deposited object is a silicon-based driving backplane. The silicon-based driving backplane is typically used to process a display panel, such as a silicon-based organic light emitting diode (OLED) display panel. Silicon-based OLED display panels have high pixels per inch (PPI), such that the sub-pixel region of silicon-based OLED display panels is smaller than that of other display panels. The ratio of an impurity particle attached to the silicon-based driving backplane to the area of its sub-pixel region during evaporation-deposition is greater, e.g., 1/3, and in less PPI products the ratio is less, e.g., 1/100. That is, the impurity particle has a greater impact on the display effect of the silicon-based OLED display panel. Therefore, the embodiments of the present disclosure are particularly suitable for the case that the to-be-evaporation-deposited object is a silicon-based driving backplane.

Exemplarily, the silicon-based driving backplane includes a plurality of display regions. That is, a plurality of display panels can be processed on one silicon-based driving backplane.

In some embodiments, an outer edge shape of the mask plate 1 is a circular. The silicon-based driving backplane is processed on a single silicon wafer, and its outer edge shape is mostly circular, such the circular mask plate 1 is adapted to the silicon-based driving backplane having this outer edge shape.

In some embodiments, the outer edge shape of the mask plate 1 is also polygonal, such as rectangular, to accommodate to-be-evaporation-deposited objects having different outer edge shapes.

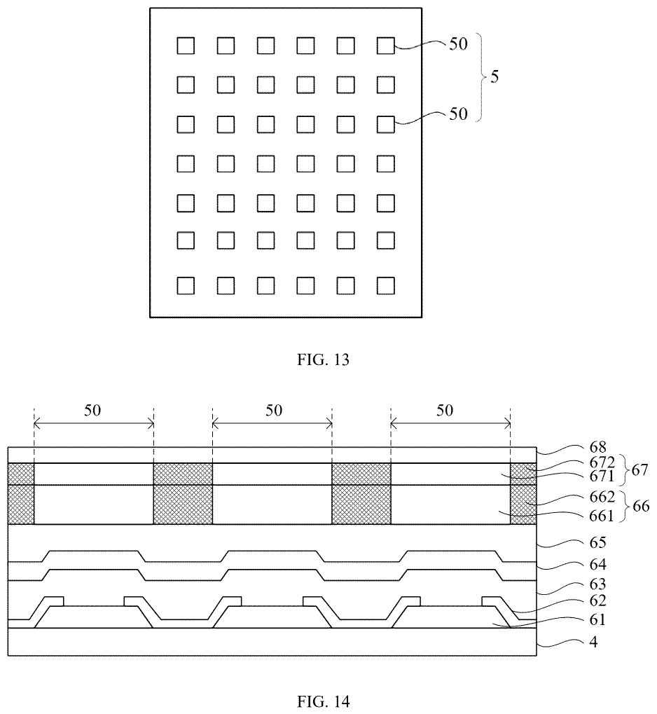

FIG. 13 is a schematic diagram of a planar structure of a silicon-based driving backplane according to some embodiments of the present disclosure. As shown in FIG. 13, the display region 5 includes a plurality of sub-pixel regions 50 distributed in an array.

FIG. 14 is a schematic diagram of a cross-sectional structure of a display panel according to some embodiments of the present disclosure. As shown in FIG. 14, a silicon-based driving backplane is selected as the to-be-evaporation-deposited object 4 and a plurality of film layer structures are processed on the silicon-based driving backplane to form a display panel. The display panel includes a first electrode layer 61, a pixel-definition layer 62, a light-emitting layer 63, a second electrode layer 64, an encapsulation layer 65, a color transfer layer 66, a color film layer 67, and a protection layer 68 which are sequentially stacked on the silicon-based driving backplane, wherein the light-emitting layer 63 and the second electrode layer 64 are processed by using the mask plate 1 in the embodiments of the present disclosure.

Exemplarily, the first electrode layer 61 includes a plurality of first electrodes distributed in an array, and the plurality of first electrodes are in one-to-one correspondence with the plurality of sub-pixel regions 50. Optionally, the first electrode layer 61 is an anode layer. Optionally, the first electrode layer 61 is made of a metal or metal oxide material, such as silver, aluminum, or the like, or a transparent conductive material, such as indium tin oxide (ITO), or the like.

In some embodiments, the pixel-definition layer 62 is configured to separate two adjacent first electrodes, and prevent crosstalk of electrical signals of the two adjacent first electrodes from affecting the display effect. Optionally, as shown in FIG. 11, the orthographic projection of the pixel-definition layer 62 on the silicon-based driving backplane is at least partially overlapped with the orthographic projection of the first electrode layer 61 on the driving backplane. Optionally, the material of the pixel-definition layer 62 is silicon oxide or silicon dioxide.

In some embodiments, the light emitting layer 63 has a whole-layer structure. Due to the design of the plurality of first electrodes and the pixel-definition layer 62, the light-emitting layer 63 has a staggered layer at the edge of the sub-pixel region 50, and the transverse conductivity is low, such that the light-emitting layer 63 has less transverse crosstalk although in a whole-layer structure.

In some embodiments, the color of the light emitted by the light emitting layer 63 is white.

In some embodiments, a hole injection layer (HIL), a hole transport layer (HTL), an electron blocking layer (EBL), a light emitting material (LEM), a hole blocking layer (HBL), and a hole blocking layer (HBL) are stacked on the light emitting layer 63 in the direction of the pixel-definition layer 62 away from the first electrode layer 61.

In some embodiments, the second electrode layer 64 has a whole-layer structure. Optionally, the second electrode layer 64 is a cathode layer. Optionally, the second electrode layer is made of a transparent conductive material, such as ITO.

In some embodiments, the encapsulation layer 65 includes a first encapsulation layer, a second encapsulation layer, and a third encapsulation layer sequentially stacked in the direction of the light emitting layer 63 away from the first electrode layer 61. The second encapsulation layer is an organic encapsulation layer for filling the uneven surface below, and the first encapsulation layer and the third encapsulation layer are inorganic encapsulation layers for protecting the second encapsulation layer and preventing external water and oxygen from entering the interior of the reality panel through the second organic encapsulation layer made of an organic material.

In some embodiments, the color transfer layer 66 includes a plurality of color transfer units 661 distributed in an array and retaining wall structures 662 disposed between the plurality of color transfer units 661, and the plurality of color transfer units 661 are in one-to-one correspondence with the plurality of sub-pixel regions 50. The plurality of color transfer units 661 are divided into a first portion, a second portion, and a third portion, and the three portions of color transfer units 661 convert white light emitted from the light emitting layer 63 into light with different colors. For example, the first portion of the plurality of color transfer units 661 converts the white light into red light, the second portion of the plurality of color transfer units 661 converts the white light into green light, and the third portion of the plurality of color transfer units 661 converts the white light into blue light.

In some embodiments, the color film layer 67 includes a plurality of color blocks 671 distributed in an array and a black matrix 672 disposed between the plurality of color blocks, and the plurality of color blocks 671 are in one-to-one correspondence with the plurality of sub-pixel regions 50. The colors of the plurality of color blocks 671 correspond to the colors of the plurality of color transfer units 661.

In one possible embodiment, in conjunction with FIGS. 1, 2, 13, and 14, an orthographic projection of an evaporation-deposition hole 10 on the second surface 102 is at least partially overlapped with and is in one-to-one correspondence with an orthographic projection of a display region 5 on the second surface 102. The sub-pixel region 50 of the high-PPI silicon-based OLED display panel has a small dimension, and a whole layer of the light emitting layer 63 and the cathode layer 64 are usually evaporation deposited by whole-side evaporation-deposition. Optionally, the dimension of the narrowest portion of the evaporation-deposition hole 10 (e.g., the third hole section 13 illustrated in FIG. 1) ranges from 3 mm to 32 mm, and the distance between the edges of the narrowest portions of two adjacent evaporation-deposition holes 10 (e.g., the third hole section 13 illustrated in FIG. 1) ranges from 1 mm to 30 mm.

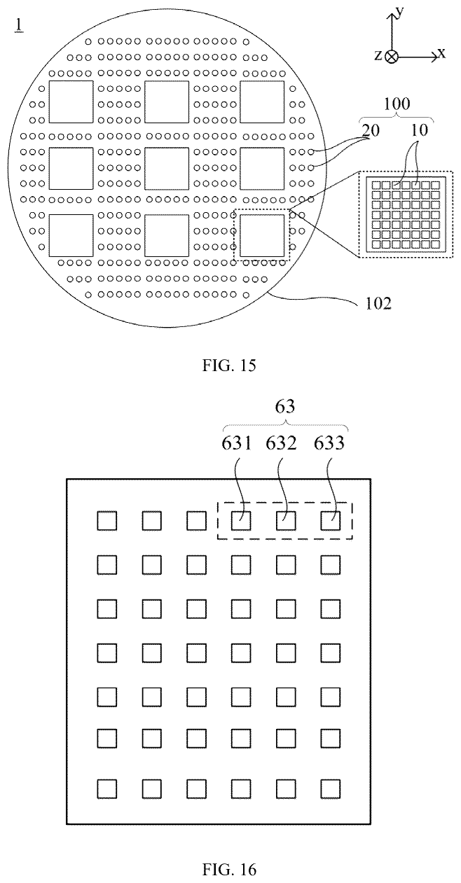

FIG. 15 is a schematic diagram of the planar structure of a mask plate according to some embodiments of the present disclosure. In another possible embodiment, in conjunction with FIG. 13 and FIG. 15, an orthographic projection of the evaporation-deposition hole 10 on the second surface 102 is at least partial overlapped with and is in one-to-one correspondence with an orthographic projection of a sub-pixel region 50 on the second surface 102. Optionally, the radial dimension of the narrowest portion of the evaporation-deposition hole 10 ranges from 3 μm to 50 μm, and the distance between the edges of the narrowest portions of two adjacent evaporation-deposition holes 10 (e.g., the third hole section 13 shown in FIG. 1) ranges from 0.1 μm to 10 μm. Optionally, in the case that the to-be-evaporation-deposited object 4 is a silicon-based driving backplane and the evaporation-deposition hole 10 on the mask plate 1 corresponds to the sub-pixel region 50, the etching silicon is applied to process the mask plate 1. The mask plate 1 processed by this manner and with this material has a higher dimensional accuracy, and the evaporation-deposition hole 10 with smaller dimensions can be processed.

It is to be noted that in the case that the orthographic projection of the narrowest portion (e.g., the third hole section 13 shown in FIG. 1) of the evaporation-deposition hole 10 on the first surface 101 is a circle, the dimension of the narrowest portion of the evaporation-deposition hole 10 refers to the diameter of the circular projection. In the case that the orthographic projection of the narrowest portion of the evaporation-deposition hole 10 (e.g., the third hole section 13 shown in FIG. 1) on the first surface 101 is a rectangular, the dimension of the narrowest portion of the evaporation-deposition hole 10 refers to the length of the short edge of the rectangular projection.

FIG. 16 is a schematic diagram of a planar structure of a light-emitting layer of another display panel according to some embodiments of the present disclosure. As shown in FIG. 16, the light-emitting layer 63 includes a plurality of light-emitting blocks distributed in an array, and the plurality of light-emitting blocks are in one-to-one correspondence with a plurality of sub-pixel regions 50 in conjunction with FIGS. 13 and 16. In some embodiments, the plurality of light-emitting blocks include a first light-emitting block 631, a second light-emitting block 632, and a third light-emitting block 633, and these three light-emitting blocks emit colors of red, green, and blue respectively.

In some embodiments, when processing the light-emitting layer including the light-emitting layer shown in FIG. 15, three different mask plates are used, and the plurality of first light-emitting blocks 631, the plurality of second light-emitting blocks 632, and the plurality of third light-emitting blocks 633 are sequentially processed by using the three mask plates, thereby acquiring the light-emitting layer. Alternatively, when processing the light-emitting layer including the light-emitting layer shown in FIG. 15, the same mask plate can be used. That is, the plurality of first light-emitting blocks 631 is processed by using the mask plate, then the mask plate is translated to process the plurality of second light-emitting blocks 632, and then the mask plate is translated to process the plurality of third light-emitting blocks 633, thereby acquiring the light-emitting layer.

In some embodiments, the driving backplane of the display panel including the light-emitting layer shown in FIG. 16 is a silicon-based driving backplane or a driving backplane corresponding to other low PPI products.

Exemplarily, the mask plate 1 includes a first mask plate and a second mask plate, and the evaporation-deposition holes of the first mask plate are within an orthographic projection of the evaporation-deposition holes of the second mask plate on the driving backplane. The first mask plate and the second mask plate are configured to process different film layers. The first mask plate can be used to process the light-emitting layer 63 in the embodiments shown in FIG. 11 or FIG. 12, and the second mask plate can be used to process the second electrode layer 64 in the embodiments shown in FIG. 11 or the second electrode layer 64 of the display panel including the light-emitting layer shown in FIG. 12. The light-emitting layer 63 and the cathode layer 64 processed by using the two kinds of mask plates cause the second electrode layer 64 to cover the light-emitting layer 63 and to cover to the edge of the display region 5, which facilitates the connection of the second electrode layer 64 to an alignment (e.g., a VSS alignment) at the edge of the display region 5.

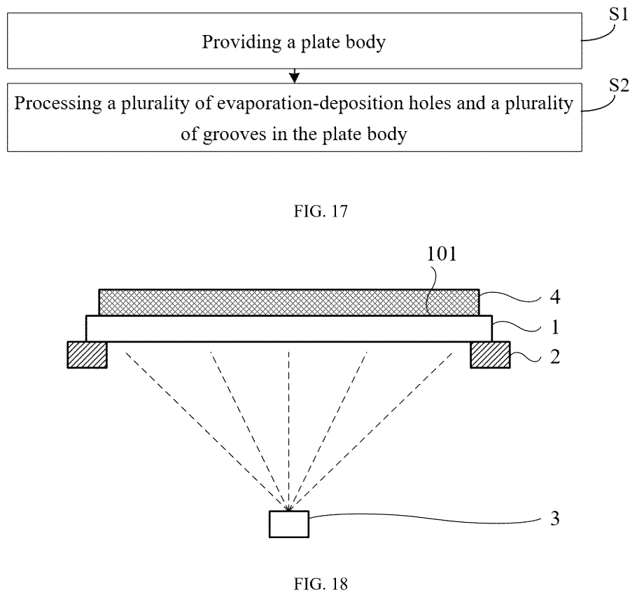

FIG. 17 is a flow diagram of a method for manufacturing a mask plate according to some embodiments of the present disclosure. As shown in FIG. 17, the method includes the following processes.

In S1, a plate body 100 is provided. The plate body 100 has a first surface and a second surface opposite to the first surface, and the first surface is in contact with a to-be-evaporation-deposited object.

In S2, a plurality of evaporation-deposition holes and a plurality of grooves are processed in the plate body 100. The evaporation-deposition holes extend through the first surface and the second surface, and the grooves are disposed on the second surface between the plurality of evaporation-deposition holes.

Exemplarily, S2 includes: processing a first groove corresponding to the first hole section 11 on the side of the first surface 101 of the plate body 100 of the mask plate 1. The bottom surface of the first groove is close to the second surface 102. In order to facilitate determination of the dimensions of the evaporation-deposition holes, a groove ring corresponding to the third hole sections 13 is usually processed on the bottom surface, and the radial dimension of an outer edge of the groove ring is the same as the radial dimension of the third hole section 13. Subsequently, a second groove corresponding to the second hole section 12 is processed on the second surface 102 side until the second groove is connected to the groove ring corresponding to the third hole section 13, such that the first groove is communicated with the second groove to form the first hole section 11, the second hole section 12, and the third hole section 13.

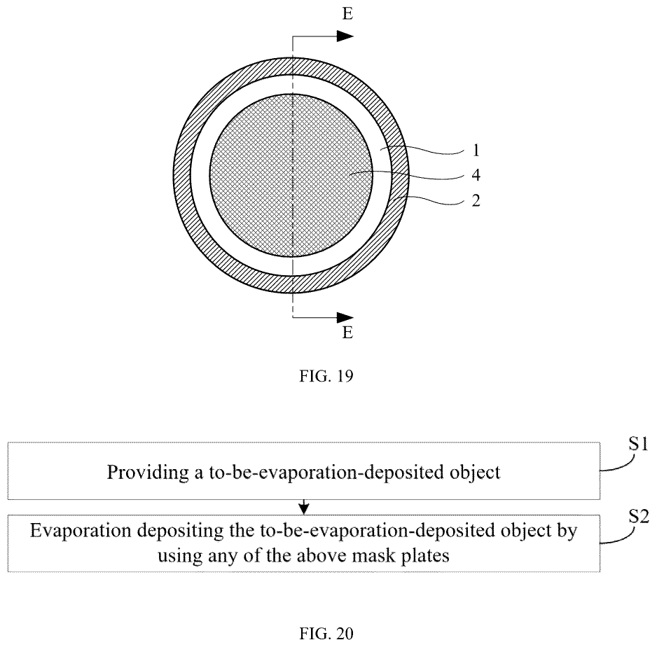

FIG. 18 is a schematic diagram of a cross-sectional structure of a mask device according to some embodiments of the present disclosure. FIG. 19 is a schematic diagram of a planar structure of a mask device according to some embodiments of the present disclosure, and FIG. 18 is a schematic diagram of a cross-sectional structure along the EE cross-sectional line in FIG. 19. As shown in FIGS. 17 and 18, the mask device includes a support element 2 and any of the above mask plates 1. The support element 2 is disposed on a side, away from the first surface 101, of the mask plate 1. The support element 2 is configured to support the mask plate and the to-be-evaporation-deposited object. The mask device has the same effect as the above mask plate, which are not repeated herein. It should be noted that in the embodiments shown in FIG. 18, in order to show the to-be-evaporation-deposited object 4, the middle portion of the mask plate 1 is empty, i.e., the shape of the mask plate 1 is a ring, and the actual planar structure of the mask plate 1 in FIG. 18 is referred to the above contents.

Exemplarily, the mask device further includes an electrostatic generator, and the electrostatic generator is configured to supply a voltage ranging from 500V to 1500V to the mask plate 1. The adsorption force of the mask plate to the evaporation-deposition material can be increased by the electrostatic adsorption effect. Since electrostatic discharge problems such as electrostatic breakdown normally occurs in the case that the electrostatic voltage supplied to the to-be-evaporation-deposited object (e.g., a silicon-based driving backplane) reaches 10 KV and above, the electrostatic at this voltage of the electrostatic generator does not harm the to-be-evaporation-deposited object.

In some embodiments, Since the support element is mostly made of a conductive material (e.g., a metallic material), the electrostatic generator supplies a voltage to the mask plate 1 through the support element.

Exemplarily, the strength of the material of the support element 2 is greater than the strength of the material of the mask plate 1 to provide better support.

In some embodiments, the material of the support element is stainless steel.

In some embodiments, the shape of the inner edge opening of the support element 2 is the same as the shape of the outer edge of the mask plate 1 to adapt the mask plate 1 with different outer edge shapes.

FIG. 20 is a flow diagram of an evaporation-deposition method according to some embodiments of the present disclosure. As shown in FIG. 20, the method includes:

In S1, a to-be-evaporation-deposited object is provided.

In S2, the to-be-evaporation-deposited object is evaporation deposited by using any of the above mask plates.

Exemplarily, the evaporation-deposition method further includes supplying a voltage ranging from 500 V to 1500 V to the mask plate during the evaporation-deposition process. Applying the electrostatic electricity during the evaporation-deposition process increases the adsorption of the mask plate to the evaporation-deposition material by electrostatic adsorption.

The above are only optional embodiments of the present disclosure and are not intended to limit the present disclosure, and any modifications, equivalent substitutions, improvements, or the like made within the spirit and principles of the present disclosure shall be included in the scope of protection of the present disclosure.

1. A mask plate, comprising a plate body, wherein the plate body has a first surface and a second surface opposite to the first surface, and the first surface being in contact with a to-be-evaporation-deposited object;
wherein a plurality of evaporation-deposition holes and a plurality of grooves are defined in the plate body, wherein the evaporation-deposition holes extend through the first surface and the second surface, and the plurality of grooves are disposed in the second surface between the plurality of evaporation-deposition holes.

2. The mask plate according to claim 1, wherein a cross-section of each of the plurality of grooves becomes progressively smaller in a direction from the second surface towards the first surface, and is perpendicular to a thickness direction of the plate body.

3. The mask plate according to claim 2, wherein a width of an opening of the each of the plurality of grooves is L1, and a distance between the openings of adjacent two of the plurality of grooves is L2, wherein L1 and L2 satisfy a relationship: L1≤L2≤2*L1.

4. The mask plate according to claim 1, wherein each of the plurality of evaporation-deposition holes comprises a first hole section and a second hole section; wherein
a first end of the first hole section is close to the second surface, a second end of the first hole section is on the first surface, and an orthographic projection of the first end on the first surface is within an orthographic projection of the second end on the first surface; and
a third end of the second hole section is close to the first surface, a fourth end of the second hole section is on the second surface, and an orthographic projection of the third end on the first surface is within an orthographic projection of the fourth end on the first surface.

5. The mask plate according to claim 4, wherein an inner wall of the first hole section is a first concave surface recessed in a direction towards the second surface.

6. The mask plate according to claim 5, wherein
an orthographic projection of a first point of the first end on the first surface is on a line connecting a second point of the second end to a center point of the second end, and a first angle is formed between a line connecting the first point to the second point and the first surface; and
an orthographic projection of a third point of the third end on the second surface is on a line connecting a fourth point of the fourth end to a center point of the fourth end, and a second angle is formed between a line connecting the third point to the fourth point and the second surface;
wherein the first angle is less than or equal to the second angle.

7. The mask plate according to claim 5, wherein
an inner wall of the second hole section is a second concave surface recessed in a direction towards the first surface; and
a radius of curvature of the first concave surface is smaller than a radius of curvature of the second concave surface.

8. The mask plate according to claim 6, wherein a surface roughness of the inner wall of the second hole section is less than a surface roughness of the inner wall of the first hole section.

9. The mask plate according to claim 3, wherein the evaporation-deposition hole comprises a first hole section, wherein a first end of the first hole section is close to the second surface, a second end of the first hole section is on the first surface, and an orthographic projection of the first end on the first surface is within an orthographic projection of the second end on the first surface.

10. The mask plate according to claim 6, wherein a dimension of the groove in a thickness direction of the plate body is smaller than a dimension of the first hole section in the thickness direction of the plate body, and the dimension of the groove in the thickness direction of the plate body is smaller than a dimension of the second hole section in the thickness direction of the plate body.

11. The mask plate according to claim 5, wherein a dimension of the groove in a thickness direction of the plate body ranges from 1 μm to 30 μm.

12. The mask plate according to claim 5, wherein a distance between the orthographic projection of the first end on the first surface and the orthographic projection of the second end on the first surface is L, and a distance between an orthographic projection of the third end on the second surface and an orthographic projection of the fourth end on the second surface is L4, wherein L1<L4 and L1<L3.

13. The mask plate according to claim 5, wherein the evaporation-deposition hole further comprises a third hole section, wherein the third hole section is connected to the first hole section and the second hole section, and is between the first hole section and the second hole section;
wherein an orthographic projection of the third hole section on the first surface is within an orthographic projection of the first hole section on the first surface, and the orthographic projection of the third hole section on the first surface is within an orthographic projection of the second hole section on the first surface.

14. The mask plate according to claim 13, wherein a dimension of the third hole section in the thickness direction of the plate body is smaller than a dimension of the first hole section in the thickness direction of the plate body.

15. The mask plate according to claim 14, wherein side walls of the third hole section are smooth.

16. The mask plate according to claim 5, wherein
a tip structure protruding away from the first surface is disposed at a bottom of each of the plurality of the grooves; or
a tip structure protruding away from the first surface is disposed at the second surface, and the tip structure is between adjacent two of the plurality of grooves.

17.-19. (canceled)

20. A method for manufacturing a mask plate, comprising:
providing a plate body, wherein the plate body has a first surface and a second surface opposite to the first surface, the first surface being in contact with a to-be-evaporation-deposited object; and
processing a plurality of evaporation-deposition holes and a plurality of grooves in the plate body, wherein the evaporation-deposition holes extend through the first surface and the second surface, and the plurality of grooves are disposed on the second surface between the plurality of evaporation-deposition holes.

21. A mask device, comprising a support element and a mask plate, wherein the mask plate comprises a plate body, wherein the plate body has a first surface and a second surface opposite to the first surface, and the first surface being in contact with a to-be-evaporation-deposited object;
wherein a plurality of evaporation-deposition holes and a plurality of grooves are defined in the plate body, wherein the evaporation-deposition holes extend through the first surface and the second surface, and the plurality of grooves are disposed in the second surface between the plurality of evaporation-deposition holes; and
the support element is disposed on a side, away from the first surface, of the plate body and arranged along an edge of the plate body.

22. The mask device according to claim 21, wherein the mask plate comprises a first mask plate and a second mask plate, an orthographic projection of the evaporation-deposition holes of the first mask plate on the to-be-evaporation-deposited object is within an orthographic projection of the evaporation-deposition holes of the second mask plate on the to-be-evaporation-deposited object;
wherein the first mask plate and the second mask plate are configured to manufacture different film layers.

23. The mask device according to claim 21, further comprising an electrostatic generator, wherein the electrostatic generator is configured to supply a voltage ranging from 500 V to 1500 V to the mask plate.
